(19) United States
(12) Patent Application Publication
(10) Pub. No.: US 2025/0393438 A1
(43) Pub. Date: Dec. 25, 2025

(54) DISPLAY DEVICE, ELECTRONIC DEVICE AND METHOD FOR MANUFACTURING THE DISPLAY DEVICE

(71) Applicant: SAMSUNG DISPLAY CO., LTD., Yongin-si (KR)

(72) Inventors: Yeong Ho KIM, Yongin-si (KR); JIHOON OH, Yongin-si (KR); Gyungeun LEE, Yongin-si (KR)

(21) Appl. No.: 19/221,190

(22) Filed: May 28, 2025

(30) Foreign Application Priority Data
Jun. 25, 2024 (KR) 10-2024-0083193
Jul. 19, 2024 (KR) 10-2024-0095545

(51) Int. Cl. H10K 59/80; H10K 59/12

(52) U.S. Cl. CPC H10K 59/80; H10K 59/1201

(57) ABSTRACT

A display device, an electronic device, and a method for manufacturing a display device are disclosed. A display device includes: a display panel including a display panel including a first area, a second area, and a bending area between the first area and the second area, the first area, the second area, and the bending area being continuous, the bending area bent such that the first area and the second area face each other in a first direction, and a spacer between the first area and the second area facing in the first direction, and the spacer is cut so as to open an exhaust hole.

### CROSS-REFERENCE TO RELATED APPLICATIONS

The present application claims priority to and the benefit of Korean Patent Application No. 10-2024-0083193, filed on Jun. 25, 2024, and Korean Patent Application No. 10-2024-0095545, filed on Jul. 19, 2024, in the Korean Intellectual Property Office, the entire disclosures of both of which are incorporated herein by reference.

### BACKGROUND

### 1. Field

The present disclosure relates to a display device, an electronic device, and a method for manufacturing a display device.

### 2. Description of the Related Art

A display device such as an organic light emitting display and a liquid crystal display includes a display panel manufactured by forming multiple layers and elements on a substrate. Recently, flexible display panels and display devices including the same have been developed.

The display device may be classified into a bendable display device, a foldable display device, a rollable display device, a stretchable display device, and the like, depending on its purpose or shape. Among these, the foldable display device may be folded and unfolded like a book.

The display device using a substrate having a flexible property may be designed to bend an edge of a display panel with a pad portion, thereby reducing dead space compared to a display device using a substrate having a rigid property. Reducing dead space may decrease a bezel width of the display device.

### SUMMARY

According to an aspect of embodiments of the present disclosure, an occurrence of bubbles may be suppressed by introducing a plurality of patterns into a spacer used in a display device.

According to one or more embodiments, a display device includes: a display panel including a display panel including a first area, a second area, and a bending area between the first area and the second area, the first area, the second area, and the bending area being continuous, the bending area bent such that the first area and the second area face each other in a first direction, and a spacer between the first area and the second area facing in the first direction, and the spacer is cut so as to open an exhaust hole.

The spacer may include a first cut line and a second cut line intersecting each other to define the exhaust hole.

The first cut line and the second cut line may be orthogonal to each other.

The first cut line may include a plurality of first cut lines parallel to each other in a second direction, and the second cut line may include a plurality of second cut lines parallel to each other in a third direction intersecting the second direction, and the spacer may include a plurality of exhaust holes in which the plurality of first cut lines and the plurality of second cut lines intersect each other.

The plurality of exhaust holes may be arranged in a matrix form along the second direction and the third direction.

The display device may further include a display driver mounted in the second area and a printed circuit board connected to an end portion of the second area.

The display device may further include a support layer having first and second surfaces facing each other, wherein the display panel may be supported on the first surface, and the spacer may be supported on the second surface.

The support layer may include a cover panel, and the cover panel may include at least one of a reinforcing layer, a cushion layer, or a shielding layer.

A cover window may be arranged on the display panel.

The support layer may include a metal plate.

The metal plate may include at least one selected from the group consisting of titanium, stainless steel, and carbon fiber reinforced plastic.

A barrier layer may be arranged between the metal plate and the display panel.

A cover window including a folding area may be arranged on the display panel.

A protective layer may be arranged on the cover window including the folding area.

According to one or more embodiments, a manufacturing method of a display device includes: preparing a display panel comprising a first area, a second area, and a bending area between the first area and the second area, the first area, the second area, and the bending area being continuous; bending the bending area such that the first area and the second area face each other in a first direction; cutting a spacer to open an exhaust hole; and arranging the spacer between the first area and the second area facing each other in the first direction.

The cutting of the spacer to open the exhaust hole may include forming a first cut line and a second cut line intersecting each other.

The first cut line and the second cut line may be cut to be orthogonal to each other.

The forming of the first cut line and the second cut line may include cutting a plurality of first cut lines parallel to each other in a second direction and a plurality of second cut lines parallel to each other in a third direction intersecting the second direction to form a plurality of exhaust holes in the spacer in which the plurality of first cut lines and the plurality of second cut lines intersect each other.

The forming of the plurality of exhaust holes may include arranging the plurality of exhaust holes in a matrix form along the second direction and the third direction.

The manufacturing method of the display device may further include attaching a support layer to a rear surface of the display panel corresponding to the first area, wherein the arranging of the spacer may include attaching the spacer to the support layer.

According to one or more embodiments, an electronic device includes: a memory, a processor to execute an application stored in the memory, and a display device including a display module to output video information provided by the application, wherein the display device comprises: a display panel comprising a first area, a second area, and a bending area between the first area and the second area, the first area, the second area, and the bending area being continuous, wherein the bending area is bent such that the first area and the second area face each other in a first direction, and a spacer between the first area and the second area facing in the first direction, wherein the spacer is cut so as to open an exhaust hole.

The spacer may include a first cut line and a second cut line intersecting each other to define the exhaust hole.

According to an aspect of embodiments of the present disclosure, a cutting line may be introduced into a spacer used in a display device to minimize or reduce the occurrence of air bubbles in the spacer.

### BRIEF DESCRIPTION OF THE DRAWINGS

FIG. 1 is a schematic perspective view of an electronic device according to an embodiment.

FIG. 2 is a perspective view of a display device included in an electronic device according to an embodiment.

FIG. 3 is a schematic cross-sectional view of a display device according to an embodiment.

FIG. 4 is an enlarged top plan view of a spacer according to an embodiment.

FIG. 5 is a schematic perspective view of a foldable electronic device according to an embodiment.

FIG. 6 is a perspective view of a display device included in a foldable electronic device according to an embodiment.

FIG. 7 is a schematic cross-sectional view of a display device according to an embodiment.

FIG. 8 is an enlarged top plan view of a spacer according to an embodiment.

FIG. 9 is a block diagram of an electronic device according to an embodiment.

FIG. 10 shows schematic diagrams of electronic devices according to various embodiments.

### DESCRIPTION OF SYMBOLS

10: cover window
10′: cover window including folding area
100: display panel
200: display driver
CP: cover panel
PLA: metal plate
SP: spacer
C1, C2: first cut line, second cut line
BU: bubbles

### DETAILED DESCRIPTION

The present disclosure will be described more fully herein with reference to the accompanying drawings, in which some embodiments of the disclosure are shown. As those skilled in the art would realize, the described embodiments may be modified in various different ways, all without departing from the spirit or scope of the present disclosure.

In order to more clearly describe the present disclosure, parts or portions that are irrelevant to the description may be omitted, and same or similar constituent elements throughout the specification are denoted by the same reference numerals.

Further, in the drawings, the size and thickness of elements may be arbitrarily illustrated for ease of description, and the present disclosure is not necessarily limited to that which is shown in the drawings. In the drawings, the thicknesses of layers, films, panels, regions, areas, etc., may be exaggerated for clarity. In the drawings, for ease of description, the thicknesses of some layers and areas may be exaggerated.

It is to be understood that when an element, such as a layer, film, region, area, or substrate, is referred to as being “on” or “above” another element, it may be directly on the other element or one or more intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly stated to the contrary, the word “comprise” and variations such as “comprises” or “comprising” are to be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

In the drawings, as symbols DR1, DR2, and DR3 used for indicating directions, “DR3” is a first direction, “DR2” is a second direction perpendicular to the first direction, and “DR1” is a third direction perpendicular to the first direction and the second direction.

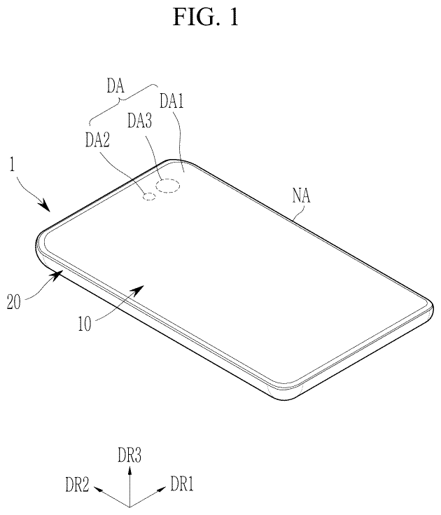

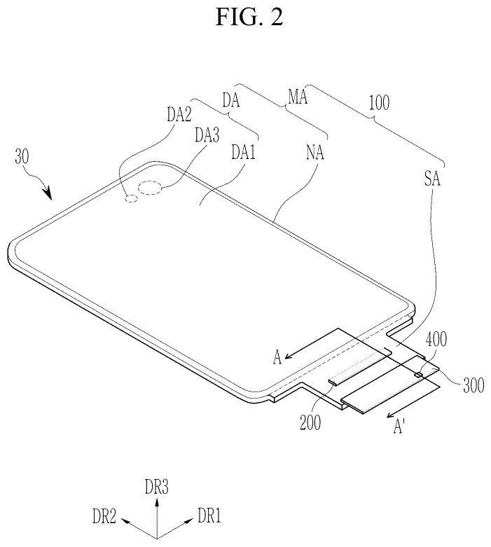

FIG. 1 is a schematic perspective view of an electronic device according to an embodiment, and FIG. 2 is a perspective view of a display device included in an electronic device according to an embodiment.

Referring to FIG. 1 and FIG. 2, an electronic device 1 may include a display screen capable of displaying an image in the first direction DR3 corresponding to a front surface in a plane defined by the second direction DR2 and the third direction DR1. The electronic device 1 may be a device having a main function to display images, such as any of a smartphone, a mobile phone, a tablet, a multimedia player, a game console, a monitor, and the like. The electronic device 1 may include a cover window 10, a housing 20, a display device 30, and the like.

The cover window 10 may include an insulating panel. For example, the cover window 10 may be made of glass, plastic, or a combination thereof. A front surface of the cover window 10 may define the front surface of the electronic device 1. An area corresponding to the display screen in the cover window 10 may be optically transparent. The cover window 10 may be disposed on the display device 30 to protect the display device 30 from an external impact or the like, and may transmit an image displayed by the display device 30. The cover window 10 may be regarded as a component of the display device 30.

The housing 20 may be made of a material having relatively high rigidity. For example, the housing 20 may include a plurality of frames and/or plates made of glass, plastic, or metal, or a combination thereof. The housing 20 may be coupled to the cover window 10, and the housing 20 and the cover window 10 coupled to each other may form an exterior of the electronic device 1 and may provide an inner space of the electronic device 1. For example, the housing 20 may form a rear surface and a side surface of the electronic device 1, and the cover window 10 may form a front surface of the electronic device 1. The display device 30 and/or the like may be disposed in an inner space defined by the cover window 10 and the housing 20, and the display device 30 and/or the like may be protected from an external environment.

The display device 30 may display an image and provide a display screen of the electronic device 1. The display device 30 may be a light emitting display device, such as an organic light emitting display device, an inorganic light emitting display device, or a quantum-dot light emitting display device.

The electronic device 1 may have any of various shapes. For example, the electronic device 1 may have a quadrangular shape with rounded corners when viewed from the front, as shown in FIG. 1. In addition, the electronic device 1 may have a shape such as a rectangular shape, a square shape, another polygonal shape, a circular shape, or an elliptical shape.

The electronic device 1 and the display device 30 may include a display area DA and a non-display area NA, respectively. The display area DA and the non-display area NA of the electronic device 1 shown in FIG. 1 may correspond to the display area DA and the non-display area NA of the display device 30 shown in FIG. 2. The display area DA is an area in which an image is displayed and may correspond to a display screen. The non-display area NA is an area in which no image is displayed. In an embodiment, the display area DA may occupy most of the area around the center on the front surface of the electronic device 1, and the non-display area NA may be around (e.g., surround) the display area DA.

The display area DA may include a first display area DA1, a second display area DA2, and a third display area DA3. The second display area DA2 and the third display area DA3 may be areas in which components, such as sensors and cameras, for adding various functions to the electronic device 1 are disposed on the rear surface. The second display area DA2 and the third display area DA3 may correspond to component areas. In an embodiment, the second display area DA2 and the third display area DA3 may be surrounded by the first display area DA1. In an embodiment, not only the first display area DA1 but also the second display area DA2 and the third display area DA3 may display images. However, positions and a number of the second display area DA2 and the third display area DA3 may be varied.

In further detail, the display device 30 may provide a display screen in the electronic device 1. The display device 30 may detect or capture the front surface of the electronic device 1. The display device 30 may have a planar shape similar to that of the electronic device 1.

In an embodiment, the display device 30 may include a display panel 100, a display driver 200, a printed circuit board 300, a touch driver 400, and the like.

The display panel 100 may be attached to the cover window 10 by an adhesive layer. The display panel 100 may include a main area MA and a sub-area SA.

The main area MA may include a display area DA in which pixels displaying images are disposed and a non-display area NA around the display area DA. In an embodiment, the display area DA may include a first display area DA1, a second display area DA2, and a third display area DA3. Components, such as sensors or cameras, may be disposed on rear surfaces of the second display area DA2 and the third display area DA3, and the second display area DA2 and the third display area DA3 may correspond to component areas.

The display area DA may emit light in the first direction DR3 from light emitting areas corresponding to the light emitting elements. For example, the display panel 100 may include a pixel circuit portion including transistors, signal lines (for example, gate lines, data lines, or voltage lines) connected to the pixel circuit portion, and a light emitting element connected to the pixel circuit portion. In an embodiment, the display panel 100 may include a pixel defining layer having an opening defining a light emitting area of each light emitting element. The light emitting element may include an organic light emitting diode including an organic light emitting layer, a quantum-dot light emitting diode including a quantum-dot light emitting layer, an inorganic light emitting diode including an inorganic semiconductor, and/or a micro-light emitting diode.

The non-display area NA may be around (e.g., surround) the display area DA. The non-display area NA may be defined as an edge area of the main area MA of the display panel 100. Circuits and/or signal lines for generating and/or transmitting various signals applied to the display area DA are disposed in the non-display area NA. For example, a gate driver (not shown) that supplies gate signals to the gate lines and fan-out lines (not shown) that connect the display driver 200 to the signal lines of the display area DA may be disposed in the non-display area NA.

The sub-area SA may be an area extending from a side of the main area MA. In an embodiment, the sub-area SA may include a flexible area capable of bending, folding, rolling, and the like. For example, the sub-area SA may be bent to overlap the main area MA in a thickness direction (the first direction DR3). The display driver 200 may be disposed in the sub-area SA, and a pad area may be disposed at an edge of the sub-area SA. The printed circuit board 300 may be connected to the pad area. In another embodiment, the sub-area SA may be omitted, and the display driver 200 and the pad area may be disposed in the non-display area NA.

The display driver 200 may output signals and voltages for driving the display panel 100. The display driver 200 may supply data voltages to the data lines. The display driver 200 may supply a power voltage to the power lines and may supply gate control signals to the gate driver. In an embodiment, the display driver 200 may be provided as an integrated circuit chip and may be mounted on the display panel 100. For example, the display driver 200 may be disposed in the sub-area SA, and may overlap the main area MA in the thickness direction (first direction DR3) by bending the sub-area SA. In another embodiment, the display driver 200 may be mounted on the printed circuit board 300.

The touch driver 400 may be provided as an integrated circuit chip and may be mounted on the printed circuit board 300. The touch driver 400 may be electrically connected to a touch sensing portion included in the electronic device 1. The touch sensing portion may be provided in the display area DA of the display panel 100. The touch driver 400 may supply an input signal (a touch driving signal) to the sensing electrodes of the touch sensing portion, and may detect an amount of change in capacitance between the sensing electrodes based on an output signal (a touch sensing signal) from the sensing electrodes. For example, the touch driving signal may be a pulse signal having a certain frequency (e.g., a predetermined frequency). The touch driver 400 may calculate whether a touch is made and touch coordinates based on the amount of change in capacitance between the sensing electrodes.

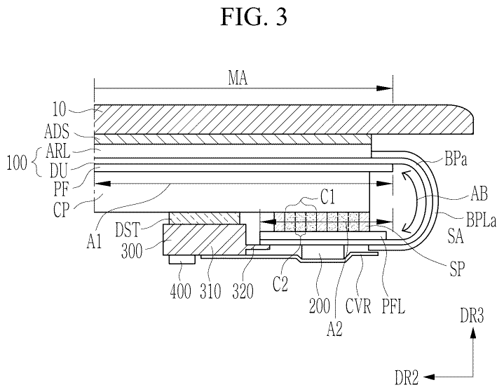

FIG. 3 illustrates a schematic cross-sectional view of a display device according to an embodiment. FIG. 3 shows a schematic cross-section of the display panel along the line A-A′ in FIG. 2 after being bent.

In the display device 30 according to an embodiment, a support layer and a spacer SP may be disposed on the rear surface of a first area A1 of the display panel, and the cover window 10 may be disposed on the front surface thereof.

The cover window 10 may be disposed on the display panel 100. The cover window 10 may protect the display panel 100. The cover window 10 may be attached to the display panel 100 by an adhesive layer ADS, such as an optically clear adhesive (OCA).

The display panel 100 may include the first area A1, a second area A2, and a bending area AB disposed between the first area A1 and the second area A2 that are distinct from each other and continuous. The bending area AB may be bent such that the second area A2 is disposed on a rear surface of the first area A1. The first area A1 and the second area A2 may be disposed to face each other in the first direction DR3 by the bending area AB. To maintain the bent state of the display panel 100, the spacer SP may be disposed between the first area A1 and the second area A2. As the display panel 100 is bent, the display driver 200 may be mounted and disposed in the second area A2. The printed circuit board 300 may be connected to an end portion of the second area A2. In an embodiment, a body portion 310 of the printed circuit board 300 may be attached to the second area A2 by a double-sided tape DST.

To describe the schematic stacked structure of the display panel 100, the display panel 100 may include a display portion DU, a touch sensing portion (not shown) disposed on the display portion DU, a reflection reducing layer ARL, and a protective film PF, and a protective sheet disposed under the display portion DU.

The display portion DU may include a substrate and a driving element layer, a light emitting element layer, and an encapsulation layer disposed on the substrate.

The substrate may be a base substrate or a base member. In an embodiment, the substrate may be a flexible substrate including a polymer resin, such as polyimide, polyamide, or polyethylene terephthalate. In an embodiment, the substrate may be a rigid substrate made of a material such as glass. The driving element layer may be disposed on the substrate. The driving element layer may include transistors and capacitors configuring pixel circuit portions that output driving currents to the light emitting elements.

The driving element layer may include gate lines, data lines, power lines, gate control lines, fan-out lines connecting the display driver 200 to the data lines, lead lines connecting the display driver 200 to the display pads DP, and the like. The driving element layer may include transistors and capacitors configuring the gate driver, and gate control lines. The driving element layer may include conductive layers, semiconductor layers, and insulating layers, and may configure and insulate transistors, capacitors, and signal lines by a combination thereof.

The light emitting element layer may be disposed on the driving element layer, and may include light emitting elements and light emitting areas corresponding thereto. The light emitting element layer may include a pixel defining layer having an opening defining the light emitting areas.

The encapsulation layer (e.g., a thin-film encapsulation layer) may cover upper and side surfaces of the light emitting element layer, and may prevent or substantially prevent external moisture or oxygen from penetrating into the light emitting element layer. The encapsulation layer may include one or more inorganic layers and one or more organic layers.

The touch sensing portion may include an encapsulation layer and may include sensing electrodes. The sensing electrodes may detect a user's touch by a mutual capacitor method and/or a magnetic capacitor method.

The reflection reducing layer ARL may be incident on the display panel 100 from the outside to reduce the amount of light reflected by the display panel 100. In an embodiment, the reflection reducing layer ARL may include a polarizing layer. In an embodiment, the reflection reducing layer ARL may include a combination of a color filter and a light blocking member instead of a polarizing layer.

The protective film PF may be attached to the rear surface of the display panel 100, and may protect the display panel 100 in a manufacturing process of the display device 30. The protective film PF may not be disposed in a bending portion BPa of the sub-area SA. A bending protection layer BPLa (or a stress neutralization layer) for relieving stress of a wiring disposed in the bending portion BPa of the sub-area SA may be disposed on the bending portion BPa of the sub-area SA.

A support layer may be disposed under the display panel. The support layer may have a first surface and a second surface opposite each other, the display panel may be supported on the first surface of the support layer, and the spacer may be supported on the second surface of the support layer. In an embodiment, a cover panel CP may be used as the support layer. In an embodiment, the cover panel CP may have a multilayer structure. In an embodiment, the cover panel CP may include a metal layer including a metal with excellent thermal conductivity and shielding performance, such as copper or aluminum, a reinforcing layer for securing strength of the protective sheet, and a cushion layer capable of preventing or substantially preventing the display panel 100 from being damaged by absorbing impact.

The display driver 200 may be mounted and disposed in the second area A2 of the display panel 100. The display driver 200, and at least a portion of the sub-area SA and the printed circuit board 300 may be covered by a cover CVR. The cover CVR may be attached to the display driver 200, the sub-area SA, and the printed circuit board 300. The cover CVR may be applied to cover the display driver 200 and at least a portion of the printed circuit board 300 to protect against electromagnetic interference (EMI) and electrostatic discharge (ESD). In addition, the cover CVR may protect the display driver 200 and the pressing portion 320 from physical damage caused by friction by preventing or substantially preventing direct contact with external objects. In an embodiment, the cover CVR may be made of a flexible material capable of shielding EMI, ESD, and the like. For example, the cover CVR may have a form of a tape including a metal layer. The metal layer of the cover CVR may include any of a metal foil, a metal fabric, a metal mesh, and the like. An adhesive layer may be disposed on a surface of the cover CVR. For example, an adhesive may be applied to a surface of the cover CVR, or a double-sided tape DST may be attached thereto.

The spacer SP may be disposed between the first area A1 and the second area A2. To reduce the non-display area of the display device, the display driver may be attached to the rear surface of the panel by bending the display panel. In this case, the spacer SP may be used as an adhesive and step compensation to fix the second area A2, which is the folded panel, in a bent state.

The spacer SP may be disposed under the cover panel CP. To prevent or substantially prevent bubbles BU from occurring, the spacer SP may be cut to open an exhaust hole. In an embodiment, the exhaust hole may be circular, elliptical, polygonal, cross-shaped, or linear.

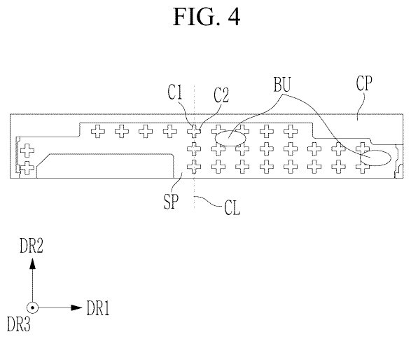

The display device according to an embodiment shows a cross-section observed from a side when the spacer SP is cut by an imaginary cutting line (CL in FIG. 4) in the case in which the exhaust hole is cross-shaped. An outer edge of the exhaust hole may correspond to a first cut line C1, and a second cut line C2 may be disposed in an inner area of the first cut line C1.

FIG. 4 illustrates an enlarged plan view of the spacer of the display device according to an embodiment.

The spacer SP may be cut to open the exhaust hole. The exhaust hole may be circular, elliptical, polygonal, cross-shaped, or linear.

Referring to FIG. 4, the exhaust hole may have the first cut line C1 and the second cut line C2 intersecting each other. In an embodiment, the first cut line C1 and the second cut line C2 may be orthogonal to each other.

The first cut line C1 may include a plurality of first cut lines C1 that are parallel in the second direction DR2, and the second cut line C2 may include a plurality of second cut lines C2 that are parallel in the third direction DR1 intersecting the second direction DR2. The spacer SP may have a plurality of exhaust holes in which the plurality of first cut lines C1 and the plurality of second cut lines C2 intersect each other. In an embodiment, the plurality of exhaust holes may be disposed in a matrix form along the second and third directions DR2 and DR1.

The spacer SP may have a first edge parallel to the third direction DR1 and a second edge parallel to the second direction DR2, and the second cut line C2 may be parallel to the first edge and the first cut line C1 may be parallel to the second edge. In an embodiment, planar widths of the first cut line C1 and the second cut line C2 may be the same within a suitable error range. The first cut line C1 and the second cut line C2 may be disposed to be inwardly spaced apart from a first edge and a second edge of the spacer.

As another example, the first cut line C1 and the second cut line C2 may obliquely extend while being orthogonal to each other and forming an angle with respect to the second direction DR2 and the third direction DR1, respectively. In an embodiment, the first cut line C1 and the second cut line C2 may extend at an inclined angle with respect to an edge of the spacer SP.

In the display device according to an embodiment, the exhaust hole of the spacer SP may be cross-shaped. If the exhaust hole is cross-shaped, a possibility of the exhaust hole being restored is low even though the adhesive portion of the spacer SP has a low modulus. In addition, tearing of the spacer SP may be minimized or reduced if the release paper is peeled off to attach the spacer SP to another layer. In addition, if the exhaust hole is cross-shaped, the exhaust hole may have a large surface area and form an air path through which bubbles may exit in four directions on a plane, such that a probability of bubbles remaining in the spacer SP may be low.

In an embodiment, to bend the edge of the display panel, the spacer SP may be used for adhesive and step compensation to fix the folded display panel. In an embodiment, the spacer SP is surface-pressed at atmospheric pressure, and during this process, the spacer SP is held and attached to the display panel using vacuum adsorption of an attachment tool. In this case, bubbles may occur in a portion vacuum-adsorbed by the attachment tool. As the area of the spacer SP increases, a probability of occurrence of bubbles BU may significantly increase. If bubbles BU occur, the thickness of the corresponding position increases, which may make assembly of the electronic device impossible or difficult due to a thickness of the display device.

In the display device according to an embodiment, the spacer SP may be cut to open the exhaust hole, thereby suppressing the formation of bubbles BU and thus providing a display device that is easily assembled when assembled into an electronic device.

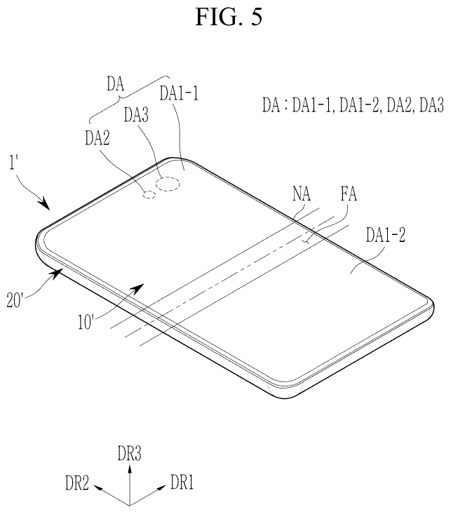

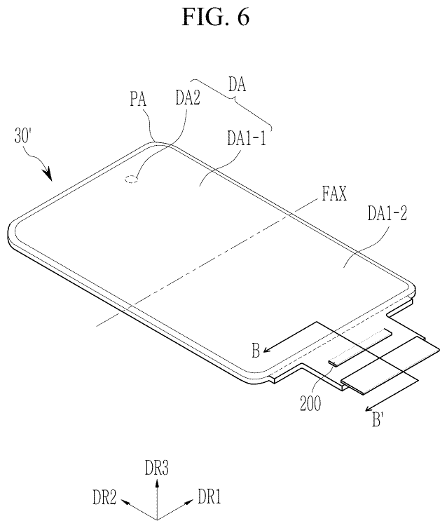

FIG. 5 illustrates a schematic perspective view of an electronic device according to an embodiment, and FIG. 6 illustrates a perspective view of a display device included in an electronic device according to an embodiment.

Referring to FIG. 5, a foldable electronic device 1′ may include a cover window 10′ including a folding area, a foldable housing 20′, and a foldable display device 30′. In an embodiment, the present configuration of the foldable electronic device 1′ may generally have a common feature with the structure described with reference to FIG. 1 and FIG. 2, and redundant descriptions thereof may be omitted.

In an embodiment, the foldable display device 30′ may include a display area DA and a peripheral area PA (herein also referred to as a non-display area). The display area DA is an area in which an image is displayed, and may be an area in which an external input is sensed. The display area DA may be an area in which a plurality of pixels is disposed, as will be described later.

The display area DA may include a first display area DA1 and a second display area DA2.

A plurality of light emitting diodes, and a plurality of pixel circuits that generate and transmit light emitting current to each of the plurality of light emitting diodes are formed in the first display area DA1. Here, one light emitting diode and one pixel circuit portion are referred to as a pixel PX. In an embodiment, one pixel circuit portion and one light emitting element are formed in a one-to-one ratio in the first display area DA1.

In an embodiment, the first display area DA1 may be divided into a (1-1)-th display area DA1-1, a (1-2)-th display area DA1-2, and a folding area FA. The (1-1)-th display area DA1-1 and the (1-2)-th display area DA1-2 may be disposed at left and right sides, respectively, with respect to (or centered on) a folding axis FAX, and the folding area FA may be disposed between the (1-1)-th display area DA1-1 and the (1-2)-th display area DA1-2. In an embodiment, when folded outwardly based on the folding axis FAX, the (1-1)-th display area DA1-1 and the (1-2)-th display area DA1-2 are disposed at both sides in the third direction DR3, and an image may be displayed in both directions. When folded inwardly based on the folding axis FAX, the (1-1)-th display area DA1-1 and the (1-2)-th display area DA1-2 may not be viewed from the outside.

The display panel included in the foldable display device 30′ also has a display area DA disposed on the front surface, and the display area DA is largely divided into a first display area DA1 (herein also referred to as a main display area) and a second display area DA2 (herein also referred to as a component area).

A plurality of light emitting diodes, and a plurality of pixel circuits that generate and transmit light emitting current to each of the plurality of light emitting diodes are formed in the first display area DA1. Here, each pixel PX may include at least one light emitting diode and at least one pixel circuit portion. The second display area DA2 may include a light transmitting area, and may additionally include a pixel for displaying an image. The second display area DA2 may at least partially overlap an optical element, such as a camera or an optical sensor. FIG. 6 shows that the second display area DA2 is provided in a circle shape at a left side of the foldable display device 30′, but the present disclosure is not limited thereto. The second display area DA2 may be provided in any of various numbers and shapes according to a number and shape of the optical elements.

The foldable display device 30′ may receive an external signal required for the optical element through the second display area DA2, or may provide a signal output from the optical element to the outside. In an embodiment, the second display area DA2 is provided to overlap the light transmitting area, such that an area of the peripheral area PA for forming the light transmitting area may be reduced.

In one or more embodiments, a boundary area may be disposed between the first display area DA1 and the second display area DA2.

The peripheral area PA may be further disposed outside the display area DA. In an embodiment, as shown in FIG. 6, the second display area DA2 is surrounded by the first display area DA1, the area of the display area DA may not be decreased due to the second display area DA2, and the area of the peripheral area PA may not be increased.

Referring to FIG. 5 and FIG. 6, in an embodiment, the foldable display device 30′ may be a foldable and flexible display device. The foldable display device 30′ may be folded outwardly or inwardly based on the folding axis FAX. When the foldable display device 30′ is folded outwardly based on the folding axis FAX, display surfaces thereof are each disposed at outer sides in the first direction DR3, such that images may be displayed in both, or opposite, directions. When the foldable display device 30′ is folded inwardly based on the folding axis FAX, the display surface thereof may not be viewed from the outside.

In FIG. 6, the peripheral area PA is also illustrated outside the display area DA, and the display driver 200 is also illustrated in the peripheral area PA. The peripheral area PA is disposed outside the display area DA and may be divided into the display driver 200, a connection wiring, and the bending area AB. In one or more embodiments, the foldable display device 30′ in which the display driver 200 is mounted and disposed in the second area A2 of the display panel 100 may be completed.

In an embodiment, as shown in FIG. 6, the display driver 200 is illustrated as being disposed in the peripheral area PA at the first direction DR3 side of the display area DA, and the display driver 200 extends in a direction parallel to the folding axis FAX, but a position of the display driver 200 may be varied.

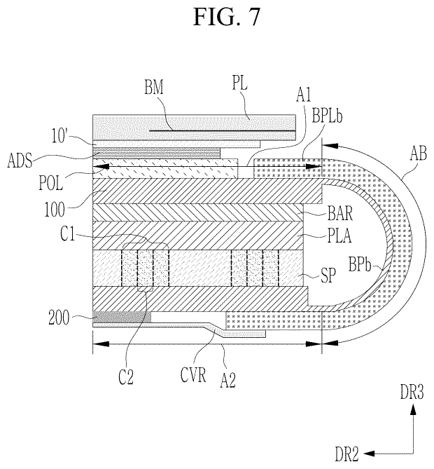

FIG. 7 illustrates a schematic cross-sectional view of a display device according to an embodiment. FIG. 7 shows a schematic cross-section of the display panel along the line B-B′ in FIG. 6 after being bent.

In the foldable display device 30′ according to an embodiment, a barrier layer BAR, a metal plate PLA, and the spacer SP may be disposed on a rear surface of a first area A1 of a display panel, and a polarizing plate POL, a cover window 10′ including a folding area, and a protective layer PL may be disposed on a front surface thereof.

The protective layer PL may be disposed on the front surface of the display panel, and may be disposed on the cover window including the folding area FA. The protective layer PL may protect the cover window including the folding area from impact and the like. In an embodiment, the protective layer PL may include at least one of polymer resins, such as polyethylene terephthalate (PET), poly(butylene terephthalate) (PBT), polycarbonate (PC), polyethylene naphthalate (PEN), polystyrene, polymethylmethacrylate (PMMA), polyvinylchloride (PVC), polyethersulfone (PES), polypropylene (PP), and polyamide (PA).

The cover window 10′ including the folding area FA may be disposed on the display panel 100. The cover window 10′ including the folding area FA may protect the display panel 100. The cover window 10′ including the folding area FA may be attached to the display panel 100 by an adhesive layer ADS, such as an optically clear adhesive (OCA). In an embodiment, the cover window WIN′ including the folding area FA may include a glass layer formed entirely thin or locally thin. The folding area FA may be disposed at a portion overlapping the folding axis FAX. A light blocking layer BM may be disposed on a portion of the cover window WIN′ including the folding area.

The polarizing plate POL may be disposed between the cover window 10′ including the folding area FA and the display panel 100. The polarizing plate POL may prevent or substantially prevent display quality from deteriorating or the internal structure of the display panel 100 from being recognized when external light is reflected after entering the display panel 100 and is provided to a user's eyes. However, in an embodiment, the polarizing plate POL may be omitted.

The display panel 100 may have a bending portion BPb. A bending protective layer BPLb (or stress neutralization layer) for relieving the stress of the wiring disposed in the bending portion BPb may be disposed on the bending portion BPb.

The barrier layer BAR disposed on the rear surface of the first area A1 of the display panel 100 may alleviate an impact applied from the rear surface of the first area A1 of the display panel 100. In one or more embodiments, the barrier layer BAR is formed in black to prevent or substantially prevent light from being provided from the rear surface to the display panel 100, and may also prevent or substantially prevent light provided from the rear surface of the display panel 100 from being reflected and provided to the front surface. In an embodiment, the barrier layer BAR may be formed of polyimide PI. The barrier layer BAR may be disposed between the metal plate PLA and the display panel 100.

A support layer may be disposed on the rear surface of the barrier layer BAR. In the foldable display device 30′, the support layer may include the metal plate PLA. The metal plate PLA may allow the display device to be maintained in a folded state when the foldable display device 30′ is folded based on the folding axis FAX, and the metal plate PLA may include a thin metal plate. The metal plate PLA may include at least one layer, for example, an upper metal plate and a lower metal plate. In an embodiment, the metal plate PLA may include at least one selected from the group consisting of stainless steel and carbon fiber reinforced plastic.

The spacer SP may be disposed on the rear surface of the metal plate PLA. The spacer SP may be disposed between the first area A1 and the second area A2.

The spacer SP may be cut to open the exhaust hole to prevent or substantially prevent bubbles BU from occurring. In an embodiment, the exhaust hole may be circular, elliptical, polygonal, cross-shaped, or linear.

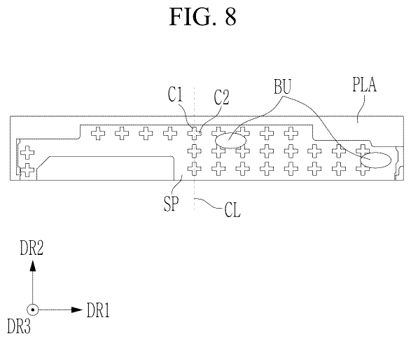

The display device according to an embodiment shows a cross-section observed from the side when the spacer SP is cut by an imaginary cutting line (CL in FIG. 8) in a case in which the exhaust hole is cross-shaped. An outer edge of the exhaust hole may correspond to the first cut line C1, and the second cut line C2 may be disposed in an inner area of the first cut line C1.

FIG. 8 illustrates an enlarged plan view of the spacer of the display device according to an embodiment.

Referring to FIG. 8, the spacer SP may be cut to open the exhaust hole. In an embodiment, the exhaust hole may be circular, elliptical, polygonal, cross-shaped, or linear, but is not limited thereto. The exhaust hole may have the first cut line C1 and the second cut line C2 intersecting each other. In an embodiment, the first cut line C1 and the second cut line C2 may be orthogonal to each other.

In an embodiment, the first cut line C1 may include a plurality of first cut lines C1 that are parallel in the third direction DR1, and the second cut line C2 may include a plurality of second cut lines C2 that are parallel in the second direction DR2 intersecting the third direction DR1. The spacer SP may have a plurality of exhaust holes in which the plurality of first cut lines C1 and the plurality of second cut lines C2 intersect each other. In an embodiment, the plurality of exhaust holes may be disposed in a matrix form along the second and third directions DR2 and DR1.

The spacer SP may have a first edge parallel to the third direction DR1 and a second edge parallel to the second direction DR2, the second cut line C2 may be parallel to the first edge and the first cut line C1 may be parallel to the second edge. In an embodiment, planar widths of the first cut line C1 and the second cut line C2 may be the same within a suitable error range. The first cut line C1 and the second cut line C2 may be disposed to be inwardly spaced apart from a first edge and a second edge of the spacer.

In an embodiment, the first cut line C1 and the second cut line C2 may obliquely extend while being orthogonal to each other and forming an angle with respect to the second direction DR2 and the third direction DR1, respectively. In this case, the first cut line C1 and the second cut line C2 may extend at an inclined angle with respect to an edge of the spacer SP.

Herein, a manufacturing method of the display device will be described with reference to FIG. 1 to FIG. 8.

A manufacturing method of the display device 30 according to an embodiment and the foldable display device 30′ according to an embodiment is as follows. A display panel is prepared, which includes a first area A1, a second area A2, and a bending area AB disposed between the first area A1 and the second area A2 that are distinct from each other and continuous. Next, the bending area AB is bent such that the first area A1 and the second area A2 face each other in the first direction. Then, the spacer SP is cut to open the exhaust hole. The spacer SP, in which the exhaust hole is formed, is disposed between the first area A1 and the second area A2 facing each other in the first direction DR3. In this case, a step, or task, of attaching the support layer to the rear surface of the display panel 100 corresponding to the first area A1 may be further included. The step, or task, of positioning the spacer SP may include a step, or task, of attaching the spacer SP to the support layer.

The step, or task, of cutting the spacer SP to open the exhaust hole may include forming the first cut line C1 and the second cut line C2 which intersect each other. In this case, the first cut line C1 and the second cut line C2 may be cut to be orthogonal to each other. In an embodiment, the exhaust hole may be circular, elliptical, polygonal, cross-shaped, or linear, but is not limited thereto. The forming of the first cut line C1 and the second cut line C2 may include forming the plurality of exhaust holes in the spacer SP in which each of the plurality of first cut lines C1 and each of the plurality of second cut lines C2 intersects each other, by cutting the plurality of first cut lines C1 parallel to each other in the second direction DR2 and the plurality of second cut lines C2 parallel to each other in the third direction DR1 intersecting the second direction DR2. The forming of the plurality of exhaust holes may include arranging the plurality of exhaust holes in a matrix form along the second and third directions DR2 and DR1.

A display device according to one or more embodiments may be applied to various electronic devices. An electronic device according to an embodiment may include the display device, and may further include modules or devices having additional functions other than the display device.

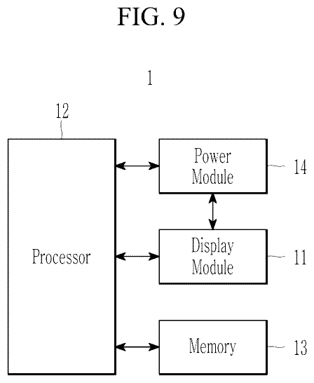

FIG. 9 is a block diagram of an electronic device according to an embodiment. Referring to FIG. 9, an electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information for operations of the processor 12 or the display module 11. When the processor 12 executes an application stored in the memory 13, video data signals and/or input control signals are transmitted to the display module 11, and the display module 11 can process the received signals to output video information through the display screen.

The power module 14 may include a power supply module, such as a power adapter or battery device, and a power conversion module that converts the power supplied by the power supply module to generate power for the operation of the electronic device 1.

At least one of components of the electronic device 1 may be included within the display device according to the above-described embodiments. In an embodiment, some of the individual modules that are functionally included within a single module may be incorporated into the display device, and others may be provided separately from the display device. For example, the display device may include the display module 11, and the processor 12, memory 13, and power module 14 may be provided in a form of other devices within the electronic device 1 that are not part of the display device.

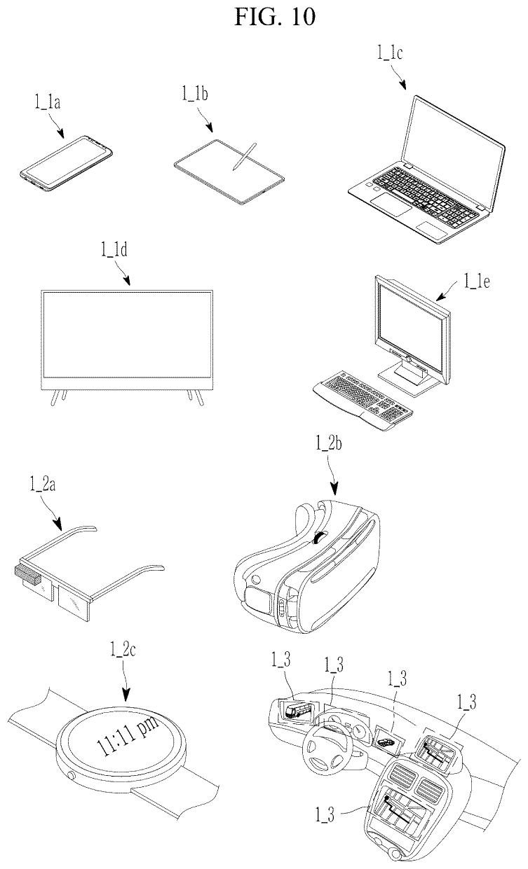

FIG. 10 shows schematic diagrams of electronic devices according to various embodiments.

Referring to FIG. 10, various electronic devices with the display device according to some embodiments may include not only image display electronic devices, such as smartphones 1_1a, tablet PCs 1_1b, laptops 1_1c, TVs 1_1d, and desktop monitors 1_1e, but also wearable electronic devices with display modules, such as smart glasses 1_2a, head-mounted displays 1_2b, and smart watches 1_2c, as well as automotive electronic devices with display modules 1_3, such as those placed on car dashboards, center fascias, CID (Center Information Display), room mirror displays, and so on.

While some embodiments of the present disclosure have been described in connection with what are presently considered to be practical embodiments, it is to be understood that the disclosure is not limited to the disclosed embodiments, but, on the contrary, is intended to cover various modifications and equivalent arrangements included within the spirit and scope of the claims.

What is claimed is:

1. A display device comprising:
a display panel comprising a first area, a second area, and a bending area between the first area and the second area, the first area, the second area, and the bending area being continuous, wherein the bending area is bent such that the first area and the second area face each other in a first direction; and
a spacer between the first area and the second area facing in the first direction,
wherein the spacer is cut so as to open an exhaust hole.

2. The display device of claim 1, wherein the spacer comprises a first cut line and a second cut line intersecting each other to define the exhaust hole.

3. The display device of claim 2, wherein the first cut line and the second cut line are orthogonal to each other.

4. The display device of claim 2, wherein
the first cut line comprises a plurality of first cut lines parallel to each other in a second direction, and the second cut line comprises a plurality of second cut lines parallel to each other in a third direction intersecting the second direction, and
the spacer comprises a plurality of exhaust holes in which the plurality of first cut lines and the plurality of second cut lines intersect each other.

5. The display device of claim 4, wherein the plurality of exhaust holes is arranged in a matrix form along the second direction and the third direction.

6. The display device of claim 1, further comprising:
a display driver mounted in the second area; and
a printed circuit board connected to an end portion of the second area.

7. The display device of claim 1, further comprising a support layer comprising first and second surfaces facing each other,
wherein the display panel is supported on the first surface, and the spacer is supported on the second surface.

8. The display device of claim 7, wherein the support layer comprises a cover panel, and the cover panel comprises at least one of a reinforcing layer, a cushion layer, or a shielding layer.

9. The display device of claim 7, wherein a cover window is arranged on the display panel.

10. The display device of claim 7, wherein the support layer comprises a metal plate.

11. The display device of claim 10, wherein the metal plate comprises at least one selected from the group consisting of titanium, stainless steel, and carbon fiber reinforced plastic.

12. The display device of claim 10, further comprising a barrier layer between the metal plate and the display panel.

13. The display device of claim 10, wherein a cover window comprising a folding area is arranged on the display panel.

14. The display device of claim 13, wherein a protective layer is arranged on the cover window comprising the folding area.

15. A manufacturing method of a display device, the manufacturing method comprising:
preparing a display panel comprising a first area, a second area, and a bending area between the first area and the second area, the first area, the second area, and the bending area being continuous;
bending the bending area such that the first area and the second area face each other in a first direction;
cutting a spacer to open an exhaust hole; and
arranging the spacer between the first area and the second area facing each other in the first direction.

16. The manufacturing method of claim 15, wherein the cutting of the spacer to open the exhaust hole comprises forming a first cut line and a second cut line intersecting each other.

17. The manufacturing method of claim 16, wherein the first cut line and the second cut line are cut to be orthogonal to each other.

18. The manufacturing method of claim 16, wherein the forming of the first cut line and the second cut line comprises cutting a plurality of first cut lines parallel to each other in a second direction and a plurality of second cut lines parallel to each other in a third direction intersecting the second direction to form a plurality of exhaust holes in the spacer in which the plurality of first cut lines and the plurality of second cut lines intersect each other.

19. The manufacturing method of claim 18, wherein the forming of the plurality of exhaust holes comprises arranging the plurality of exhaust holes in a matrix form along the second direction and the third direction.

20. An electronic device comprising:
a memory;
a processor to execute an application stored in the memory; and
a display device comprising a display module to output video information provided by the application,
wherein the display device comprises:
a display panel comprising a first area, a second area, and a bending area between the first area and the second area, the first area, the second area, and the bending area being continuous, wherein the bending area is bent such that the first area and the second area face each other in a first direction; and
a spacer between the first area and the second area facing in the first direction,
wherein the spacer is cut so as to open an exhaust hole.
